(19) United States
(12) Patent Application Publication
(10) Pub. No.: US 2024/0038588 A1
(43) Pub. Date: Feb. 1, 2024

(54) METHODS OF FORMING THE MICROELECTRONIC DEVICES, AND RELATED MICROELECTONIC DEVICES AND ELECTRONIC SYSTEMS

(71) Applicant: Micron Technology, Inc., Boise, ID (US)

(72) Inventors: Terrence B. McDaniel, Boise, ID (US); Vinay Nair, Boise, ID (US); Russell A. Benson, Boise, ID (US); Christopher W. Petz, Boise, ID (US); Si-Woo Lee, Boise, ID (US); Silvia Borsari, Boise, ID (US); Ping Chieh Chiang, Boise, ID (US); Luca Fumagalli, Rio Rancho, NM (US)

(21) Appl. No.: 17/815,359

(22) Filed: Jul. 27, 2022

(51) Int. Cl. H01L 21/768; H01L 27/108

(52) U.S. Cl. CPC H01L 21/76897; H01L 27/10855; H01L 27/10885

(57) ABSTRACT

A method of forming a microelectronic device comprises forming interlayer dielectric material over a base structure comprising semiconductive structures separated from one another by insulative structures. Sacrificial line structures separated from one another by trenches are formed over the interlayer dielectric material. The sacrificial line structures horizontally overlap some of the semiconductive structures, and the trenches horizontally overlap some other of the semiconductive structures. Plug structures are formed within horizontal areas of the trenches and extend through the interlayer dielectric material and into the some other of the semiconductive structures. The sacrificial line structures are replaced with additional trenches. Conductive contact structures are formed within horizontal areas of the additional trenches and extend through the interlayer dielectric material and into the some of the semiconductive structures. Conductive line structures are formed within the additional trenches and in contact with the conductive contact structures.

### TECHNICAL FIELD

Embodiments disclosed herein relate to microelectronic devices and microelectronic device fabrication. More particularly, embodiments of the disclosure relate to methods of forming microelectronic devices including self-aligned contact structures, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

A relatively common microelectronic device is a memory device. A memory device may include a memory array having a number of memory cells arranged in a grid pattern. One type of memory cell is a dynamic random access memory (DRAM). In the simplest design configuration, a DRAM cell includes one access device, such as a transistor, and one storage device, such as a capacitor. Modern applications for memory devices can utilize vast numbers of DRAM unit cells, arranged in an array of rows and columns. The DRAM cells are electrically accessible through digit lines and word lines arranged along the rows and columns of the array.

Reducing the dimensions and spacing of memory device features places ever increasing demands on the methods used to form the memory device features. For example, DRAM device manufacturers face a tremendous challenge on reducing the DRAM cell area as feature spacing decreases to accommodate increased feature density. Conventional approaches to reducing spacing between neighboring digit lines often reduce margin for error (e.g., alignment errors), and can result in undesirable shorts and/or undesirable capacitive coupling effects without complex and time-consuming feature alignment methodologies.

### BRIEF DESCRIPTION OF THE DRAWINGS

FIGS. 1 through 16 are simplified, partial cross-sectional views (FIGS. 1, 2, 3, 4, 5, 6, 7B, 7C, 8, 9, 10A, 11, 12, 13, 14, 15, and 16) and simplified top-down views (FIGS. 7A and 10B) of a microelectronic device structure at different processing stages of a method of forming a microelectronic device, in accordance with embodiments of the disclosure.

FIG. 17 is a functional block diagram of a memory device, in accordance with an embodiment of the disclosure.

FIG. 18 is a schematic block diagram of an electronic system, in accordance with embodiments of the disclosure.

### DETAILED DESCRIPTION

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of a microelectronic device or a complete process flow for manufacturing the microelectronic device and the structures described below do not form a complete microelectronic device. Only those process acts and structures necessary to understand the embodiments described herein are described in detail below. Additional acts to form a complete microelectronic device may be performed by conventional techniques.

Drawings presented herein are for illustrative purposes only, and are not meant to be actual views of any particular material, component, structure, microelectronic device, or microelectronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms of the terms “a,” “an,” and “the” are intended to include the plural forms as well, unless the context clearly indicates otherwise.

As used herein, the term “and/or” includes any and all combinations of one or more of the associated listed items.

As used herein, the terms “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operatively connected with each other, such as electrically connected through a direct Ohmic connection or through an indirect connection (e.g., by way of another structure).

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional non-volatile memory, such as conventional NAND memory; conventional volatile memory, such as conventional DRAM), but also includes an application specific integrated circuit (ASIC) (e.g., a system on a chip (SoC)), a microelectronic device combining logic and memory, and a graphics processing unit (GPU) incorporating memory.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. For example, these terms may include a direction that is parallel to a primary surface of the substrate on which the referenced material or structure is located. The width and length of a respective material or structure may be defined as dimensions in a horizontal plane. With reference to the figures, the “horizontal” direction may be perpendicular to an indicated “Z” axis and may be parallel to an indicated “X” axis and an indicated “Y” axis. The height of a respective material or feature (e.g., structure) may be defined as a dimension in a vertical plane.

As used herein, features (e.g., regions, structures, devices) described as “neighboring” one another means and includes features of the disclosed identity (or identities) that are located most proximate e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “intersection” means and includes a location at which two or more features (e.g., regions, structures, materials, trenches, devices) or, alternatively, two or more portions of a single feature meet. For example, an intersection between a first feature extending in a first direction (e.g., an X-direction) and a second feature extending in a second direction (e.g., a Y-direction) different than the first direction may be the location at which the first feature and the second feature meet.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), gallium oxide (GaₓO), indium oxide (InₓO), tin oxide (SnₓO), titanium oxide (TiₓO), other binary metal oxides, zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure, a region) do not vary throughout different portions (e.g., different horizontal portions, different vertical portions) of the feature. Conversely, as used herein, the term “heterogeneous” means relative amounts of elements included in a feature (e.g., a material, a structure, a region) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

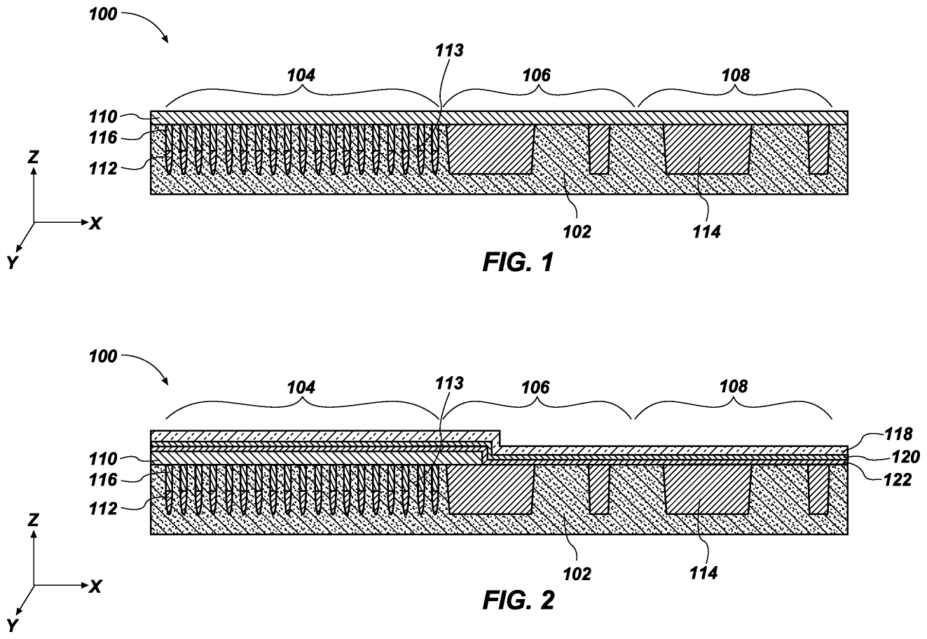

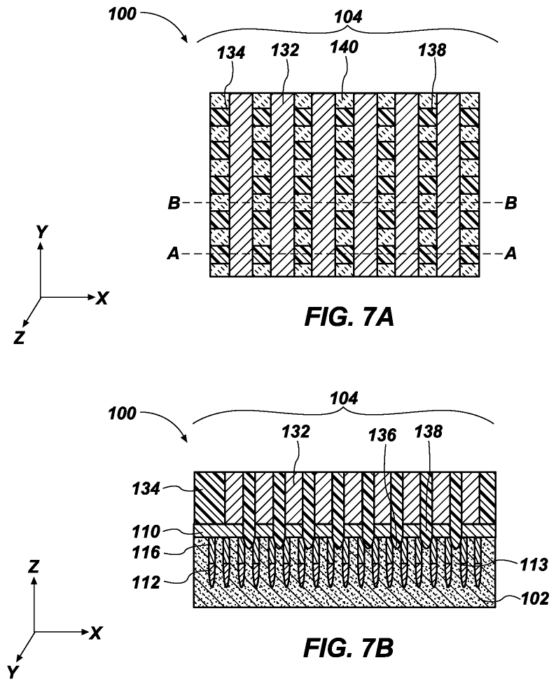

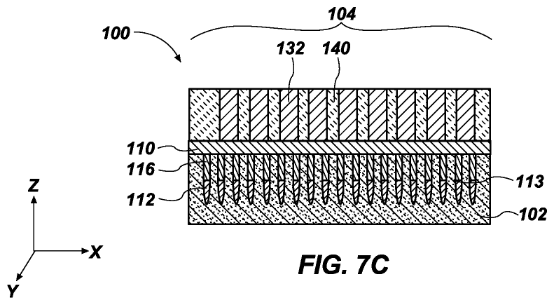

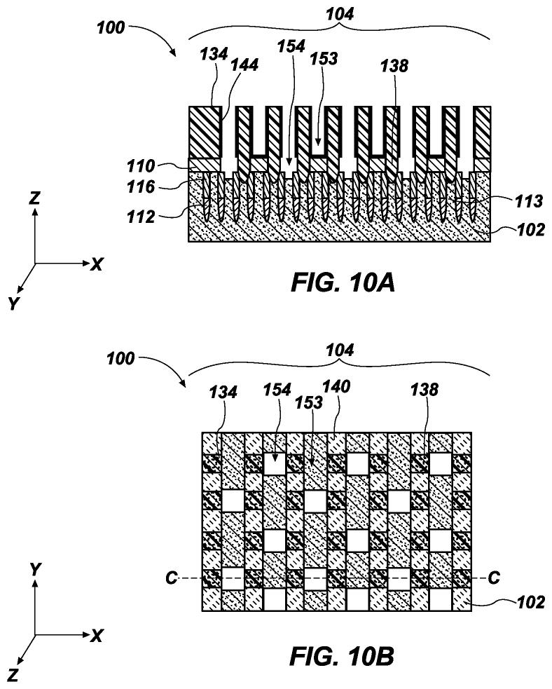

FIGS. 1 through 16 are simplified, partial cross-sectional views (FIGS. 1, 2, 3, 4, 5, 6, 7B, 7C, 8, 9, 10A, 11, 12, 13, 14, 15, and 16) and simplified top-down views (FIGS. 7A and 10B) of a microelectronic device structure (e.g., a memory device structure, such as a DRAM structure) at different processing stages of a method of forming a microelectronic device (e.g., a memory device, such as a DRAM device), in accordance with embodiments of the disclosure. With the description provided below, it will be readily apparent to one of ordinary skill in the art that the methods described herein may be used to form various microelectronic devices, such as to form microelectronic devices where three-dimensional (3D) scaling is advantageous.

Referring to FIG. 1, a microelectronic device structure 100 may be formed to include a base structure 102, interlayer dielectric (ILD) material 110, conductive line structures 112 (e.g., word line structures, access line structures), shallow trench isolation (STI) structures 114, and insulative structures 116 (e.g., word line capping structures, access line capping structures). The ILD material 110 may be formed on or over the base structure 102. The conductive line structures 112 and STI structures 114 may be underlie the ILD material 110, and may individually be positioned within the vertically boundaries of the base structure 102. The conductive line structures 112 and STI structures 114 may be horizontally offset from one another within the base structure 102. The insulative structures 116 may be positioned vertically between the ILD material 110 and the conductive line structures 112. The insulative structures 116 may be horizontally offset from one another within the base structure 102, and individual insulative structures 116 may at least partially horizontally overlap individual conductive line structures 112. The foregoing features and addition features of the microelectronic device structure 100 at the process stage depicted in FIG. 1 are described in further detail below.

Still referring to FIG. 1, the microelectronic device structure 100 may be divided into an array region 104, an edge of array (EOA) region 106, and periphery region 108. The EOA region 106 and the periphery region 108 may together form a non-array region of the microelectronic device structure 100. The EOA region 106 may be horizontally interposed between the array region 104 and the periphery region 108. One or more arrays of memory cells, including arrays of access devices (e.g., transistors) and arrays of storage node devices (e.g., capacitors) operatively associated with the arrays of access devices, may subsequently be formed within a horizontal area of the array region 104. The arrays of memory cells may not subsequently be formed within horizontal areas of the EOA region 106 and the periphery region 108 (e.g., the arrays of memory cells may be substantially confined within the horizontal area of the array region 104.

As shown in FIG. 1, base structure 102 may horizontally extend (e.g., in the X-direction and in the Y-direction) across the array region 104, the EOA region 106, and the periphery region 108 of the microelectronic device structure 100. The base structure 102 may comprise a base material or construction upon which additional features (e.g., materials, structures, devices) of the microelectronic device structure 100 are formed. The base structure 102 may, for example, be formed of and include one or more of a semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α-Al₂O₃), and silicon carbide). For example, the base structure 102 may comprise a conventional silicon substrate (e.g., a conventional silicon wafer), or another bulk substrate comprising a semiconductor material.

Still referring to FIG. 1, the EOA region 106 of the microelectronic device structure 100 may be horizontally interposed between the array region 104 and the periphery region 108 of the microelectronic device structure 100. The periphery region 108 may be located at and/or horizontally proximate a peripheral boundary (e.g., an outer horizontal boundary) of the microelectronic device structure 100. The EOA region 106 and the periphery region 108 of the microelectronic device structure 100 may be configured and employed for various circuitry (e.g., various conductive routing structures) for a microelectronic device (e.g., DRAM device) subsequently formed using the methods of the disclosure.

Within horizontal areas of the EOA region 106 and the periphery region 108 of the microelectronic device structure 100 the STI structures 114 may vertically extend (e.g., in the Z-direction) at least partially through the base structure 102. In some embodiments, the STI structures 114 only partially vertically extend through the base structure 102. STI structures 114 horizontally neighboring one another may be horizontally separated from one another by portions of the base structure 102. Each of the STI structures 114 may have substantially the same geometric configuration (e.g., the same dimensions, the same shape), or at least one of the STI structures 114 may have a different geometric configuration (e.g., one or more different dimensions, a different shape) than at least one other of the STI structures 114. The STI structures 114 may individually be formed of and include insulative material. In some embodiments, the STI structures 114 are formed of and include silicon oxide (e.g., SiO₂).

The array region 104 of the microelectronic device structure 100 may subsequently be formed to include arrays of memory cells and associated features (e.g., conductive contact structures, conductive line structures), as described in further detail below. The array region 104 may also be formed to include various circuitry, such as various logic circuitry (e.g., various complemental metal-oxide-semiconductor (CMOS) devices, various conductive routing structures) for operation of the subsequently formed memory cells. The array region 104 may be considered an “active region” of the microelectronic device structure 100.

Within the horizontal area of the array region 104 of the microelectronic device structure 100, the conductive line structures 112 and the insulative structures 116 may vertically extend into the base structure 102. The conductive line structures 112 may vertically underlie the insulative structures 116. Upper boundaries (e.g., upper surfaces) of the conductive line structures 112 are vertically offset (e.g., vertically underlie) an upper boundary (e.g., an upper surface) of the base structure 102. An insulative material (e.g., gate dielectric material, dielectric oxide material) may be interposed between (e.g., may extend from and between) the conductive line structures 112 and the base structure 102. The insulative material may electrically isolate the conductive line structures 112 from the base structure 102. Upper boundaries (e.g., upper surfaces) of the insulative structures 116 may be substantially coplanar with the upper boundary of the base structure 102.

The conductive line structures 112 may be formed to vertically extend partially (e.g., less than completely) through the base structure 102. In some embodiments, the conductive line structures 112 are employed as word line structures (e.g., access line structures) of the microelectronic device structure 100. Each of the conductive line structures 112 may be formed to exhibit substantially the same dimensions and shape as each other of the conductive line structures 112, or at least one of the conductive line structures 112 may be formed to exhibit one or more of different dimensions and a different shape than at least one other of the conductive line structures 112. As a non-limiting example, each of the conductive line structures 112 may be formed to exhibit substantially the same vertical dimension(s) and substantially the same vertical cross-sectional shape(s) as each other of the conductive line structures 112; or at least one of the conductive line structures 112 may be formed to exhibit one or more of different vertical dimension(s) and different vertical cross-sectional shape(s) than at least one other of the conductive line structures 112. In some embodiments, the conductive line structures 112 are all formed to vertically extend to and terminate at substantially the same depth within the base structure 102. In additional embodiments, at least one of the conductive line structures 112 is formed to vertically extend to and terminate at a relatively deeper depth within the base structure 102 than at least one other of the conductive line structures 112. As another non-limiting example, each of the conductive line structures 112 may be formed to exhibit substantially the same horizontal dimension(s) and substantially the same horizontal cross-sectional shape(s) as each other of the conductive line structures 112; or at least one of the conductive line structures 112 may be formed to exhibit one or more of different horizontal dimension(s) (e.g., relatively larger horizontal dimension(s), relatively smaller horizontal dimension(s)) and different horizontal cross-sectional shape(s) than at least one other of the conductive line structures 112. In some embodiments, at least one of the conductive line structures 112 is formed to have one or more different horizontal dimensions (e.g., in the X-direction and/or in the Y-direction) than at least one other of the conductive line structures 112.

The conductive line structures 112 may individually be formed of and include conductive material, such as such one or more of at least one metal, at least one an alloy, at least one conductive metal-containing material, and at least one conductively doped semiconductor material. In some embodiments, the conductive line structures 112 are individually formed of and include tungsten (W). The conductive line structures 112 may each be substantially homogeneous, or more or more of the conductive line structures 112 may individually be heterogeneous. At least one of the conductive line structures 112 may, for example, be formed of and include a stack of at least two different conductive materials.

The insulative structures 116 may be vertically interposed between the ILD material 110 and the conductive line structures 112. The insulative structures 116 may individually be formed of insulative material, such as one or more of a dielectric oxide material (e.g., silicon dioxide; phosphosilicate glass; borosilicate glass; borophosphosilicate glass; fluorosilicate glass; aluminum oxide; a combination thereof), a dielectric nitride material (e.g., SiN_{y}, a dielectric an oxynitride material (e.g., SiOₓN_{y}), a dielectric carbonitride material (e.g., SiCₓN_{y}), and a dielectric carboxynitride material (e.g., SiOₓC_{y}N_{z}), and amorphous carbon. In some embodiments, the insulative structures 116 are individually formed of and include silicon oxide (e.g., SiOₓ, such as SiO₂). In additional embodiments, the insulative structures 116 are individually formed of and include silicon nitride (e.g., SiN_{y}, such as Si₃N₄). The insulative structures 116 may individually be substantially homogeneous, or one or more of the insulative structures 116 may be heterogeneous. At least one of the insulative structures 116 may, for example, be formed of and include a stack of at least two different insulative materials.

Although depicted as having rectangular vertical cross-sectional shapes in FIG. 1, the insulative structures 116 may exhibit a tapered vertical cross-sectional profiles. For example, an upper portion of an individual insulative structure 116 may have a greater horizontal dimension (e.g., width) than a lower portion of the insulative structure 116. In some embodiments, horizontal centers of the insulative structures 116 are substantially horizontally aligned (e.g., in the X-direction) with horizontal centers of the conductive line structures 112 in physical contact therewith; and the insulative structures 116 are substantially confined within horizontal areas of the conductive line structures 112 in physical contact therewith. In additional embodiments, horizontal centers of one or more of the insulative structures 116 are horizontally offset from (e.g., in the X-direction) with horizontal centers of the conductive line structures 112 in physical contact therewith; and/or one or more the insulative structures 116 horizontally extend beyond the horizontal areas of the conductive line structures 112 in physical contact therewith.

Horizontally interposed between neighboring conductive line structures 112 and the neighboring insulative structures 116 are projecting portions 113 of the base structure 102. The projecting portions 113 of the base structure 102 may be formed of and include semiconductor material (e.g., silicon, such as polycrystalline silicon). The projecting portions 113 of the base structure 102 are also reference to herein as “semiconductive projections” or “semiconductive structures.” The projecting portions 113 of the base structure 102 vertically extend past upper boundaries of the conductive line structures 112, and at least to upper boundaries of the insulative structures 116. Insulative material (e.g., gate dielectric material, dielectric oxide material) may be interposed between the projecting portions 113 of the base structure 102 and the conductive line structures 112.

Still referring to FIG. 1, the ILD material 110 is formed to horizontally extend (e.g., in the X-direction, in the Y-direction) across each of the array region 104, the EOA region 106, and the periphery region 108 of the microelectronic device structure 100. The ILD material 110 may be formed of and include insulative material. In some embodiments, the ILD material 110 is formed of and includes silicon nitride (e.g., SiN_{y}, such as Si₃N₄). In additional embodiments, the ILD material 110 is formed of and includes different insulative material, such as low-K dielectric material (e.g., one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{y}N_{z})).

The ILD material 110 may be formed to a desired thickness (e.g., vertical dimension in the Y-direction), such as a thickness within range of from about 1 nanometer (nm) to about 20 nm (e.g., from about 4 nm to about 12 nm, from about 4 nm to about 6 nm). In some embodiments, the ILD material 110 is formed to a vertical thickness within a range of from about 4 nm to about 6 nm.

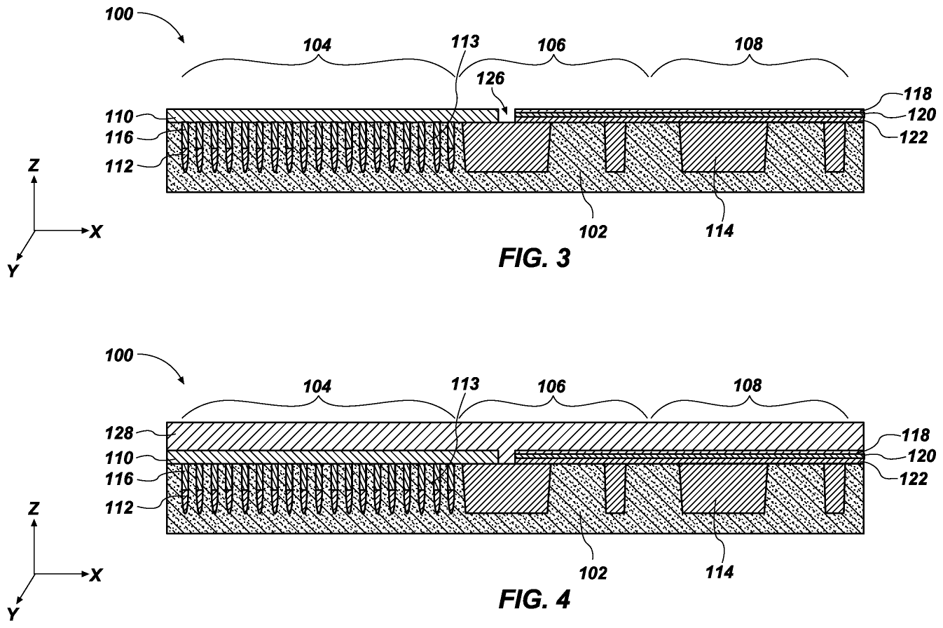

FIG. 2 is a simplified, partial cross-sectional view of the microelectronic device structure 100 at a processing stage following the processing stage of FIG. 1. As shown in FIG. 2, portions of the ILD material 110 within the EOA region 106 and the periphery region 108 may be removed to expose portions of the base structure 102 and the STI structures 114, and then each of a gate dielectric material 122, a first gate material 120, and a second gate material 118 may be formed. The gate dielectric material 122 may be formed (e.g., conformally formed) on or over exposed surfaces of the base structure 102, the STI structures 114, and a remaining (e.g., unremoved) portion of the ILD material 110. The first gate material 120 may be formed (e.g., conformally formed) on or over the gate dielectric material 122. The second gate material 118 may be formed (e.g., conformally formed) on or over the first gate material 120.

As shown in FIG. 2, in some embodiments, the ILD material 110 is substantially completely removed from the periphery region 108, is partially (e.g., less than completely) removed from the EOA region 106, and is substantially maintained within the array region 104. For example, a remaining portion of the ILD material 110 may horizontally terminate within a horizontal area of a STI structure 114 within the EOA region 106. In additional embodiments, the ILD material 110 is substantially completely removed from each of the periphery region 108 and the EOA region 106, and is substantially maintained within the array region 104. For example, a remaining portion of the ILD material 110 may horizontally terminate at or proximate a horizontal boundary of a STI structure 114 within the EOA region 106. Portions of the ILD material 110 within the periphery region 108 and the EOA region 106 may be removed while maintaining additional portions of the ILD material 110 within array region 104 using conventional material removal processes (e.g., conventional photolithographic patterning processes), which are not described in detail herein.

The gate dielectric material 122 may be formed of and include insulative material, such as one or more of a dielectric oxide material (e.g., silicon dioxide; phosphosilicate glass; borosilicate glass; borophosphosilicate glass; fluorosilicate glass; aluminum oxide; a combination thereof), a dielectric nitride material (e.g., SiN_{y}, a dielectric an oxynitride material (e.g., SiOₓN_{y}), a dielectric carbonitride material (e.g., SiCₓN_{y}), and a dielectric carboxynitride material (e.g., SiOₓC_{y}N_{z}), and amorphous carbon. In some embodiments, the gate dielectric material 122 is formed of and includes high-K dielectric material, such as high-K dielectric oxide material (e.g., one or more hafnium oxide (HfOₓ), niobium oxide (NbOₓ), titanium oxide (TiOₓ), aluminum oxide (AlOₓ), and zirconium oxide (ZrOₓ)).

The first gate material 120 may be formed of and include conductive material, such as one or more of at least one metal (e.g., one or more of tungsten, titanium, nickel, platinum, gold), at least one metal alloy, at least one metal-containing material (e.g., one or more of at least one metal nitride, at least one metal silicide, at least one metal carbide, at least one conductive metal oxide), and at least one conductively doped semiconductor material (e.g., conductively doped silicon, conductively doped germanium, conductively doped silicon germanium). In some embodiments, the first gate material 120 is formed of and includes tungsten (W). In additional embodiments, the first gate material 120 is formed of and includes conductively doped semiconductor material, such as conductively doped silicon germanium (SiGe) material. For example, the first gate material 120 may be formed of and include epitaxial SiGe material doped with at least one N-type dopant (e.g., one or more of arsenic, phosphorous, antimony, and bismuth) or at least one P-type dopant (e.g., one or more of boron, aluminum, and gallium).

The second gate material 118 may be formed of and include additional conductive material. In some embodiments, the first gate material 120 is formed of and includes conductively doped semiconductor material, such as conductively doped polysilicon. For example, the second gate material 118 may be formed of and include polysilicon doped with at least one N-type dopant (e.g., one or more of arsenic, phosphorous, antimony, and bismuth) or and least one P-type dopant (e.g., one or more of boron, aluminum, and gallium).

FIG. 3 is a simplified, partial cross-sectional view of the microelectronic device structure 100 at a processing stage following the processing stage of FIG. 2. As shown in FIG. 3, portions of the gate dielectric material 122, the first gate material 120, and the second gate material 118 may be removed from the array region 104 and the EOA region 106, while maintaining additional portions of the gate dielectric material 122, the first gate material 120, and the second gate material 118 within the EOA region 106 and the periphery region 108. The removal process may expose (e.g., uncover) portions of the ILD material 110 within the array region 104 and the EOA region 106, and may also form a trench 126 horizontally interposed between the ILD material 110 and the remaining portions of the gate dielectric material 122, the first gate material 120, and the second gate material 118. The trench 126 may, for example, be positioned within the EOA region 106 and may partially expose an upper surface of a STI structure 114 within the EOA region 106.

As shown in FIG. 3, an upper boundary of a remaining portion of the second gate material 118 may be substantially coplanar with an upper boundary of a remaining portion of the ILD material 110. In additional embodiments, the upper boundary of the remaining portion of the ILD material 110 is vertically offset from (e.g., vertically overlies, vertically underlies) the upper boundary of a remaining portion of the second gate material 118.

In some embodiments, the trench 126 between the remaining portion of the ILD material 110 and the remaining portions of the gate dielectric material 122, the first gate material 120, and the second gate material 118 is positioned within a horizontal area of an STI structure 114 within the EOA region 106. In addition, a horizontal center of the trench 126 in the X-direction may, for example, be substantially aligned with a horizontal center of the STI structure 114 exposed thereby. In additional embodiments, the trench 126 is positioned outside of the horizontal area of the STI structure 114 most proximate thereto, or the horizontal center of the trench in the X-direction is offset from the horizontal center of the STI structure 114 exposed thereby.

FIG. 4 is a simplified, partial cross-sectional view of the microelectronic device structure 100 at a processing stage following the processing stage of FIG. 3. As shown in FIG. 4, sacrificial material 128 may be formed (e.g., non-conformally formed) over exposed surfaces of the microelectronic device structure 100. The sacrificial material 128 may cover remaining portions of the ILD material 110, the gate dielectric material 122, the first gate material 120, and the second gate material 118, and may also fill the trench 126 (FIG. 3). An upper boundary of the sacrificial material 128 may be substantially planar, and a lower boundary of the sacrificial material 128 may be at least partially non-planar.

The sacrificial material 128 may be formed of and include insulative material. In some embodiments, the sacrificial material 128 is formed of includes dielectric nitride material (e.g., SiN_{y}, such as Si₃N₄). In additional embodiments, the sacrificial material 128 is formed of and includes a dielectric oxide material (e.g., SiOₓ, such as SiO₂). The sacrificial material 128 may be substantially homogeneous, or the sacrificial material 128 may be heterogeneous. The sacrificial material 128 may be formed to a desired vertical height above upper boundaries of the remaining portions of the ILD material 110 and the second gate material 118.

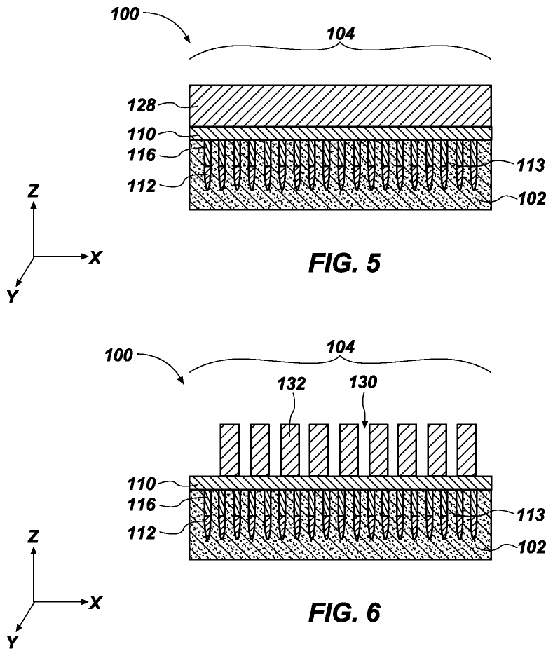

FIGS. 5 through 16 are simplified, partial cross-sectional views (FIGS. 5, 6, 7B, 7C, 8, 9, 10A, 11, 12, 13, 14, 15, and 16) and simplified top-down views (FIGS. 7A and 10B) of the array region 104 of the microelectronic device structure 100 at various processing stages of the method of forming a microelectronic device of the disclosure. The processing stage of FIG. 5, and associated features of the microelectronic device structure 100, may correspond to the processing stage previously described with reference to FIG. 4. For example, at the processing stage of FIG. 5, the microelectronic device structure 100 includes the sacrificial material 128 formed on or over the ILD material 110. In addition, FIGS. 6 through 16 depict the array region 104 of the microelectronic device structure 100 at different processing stages following that of FIGS. 4 and 5, as described in further detail below. Although only the array region 104 is depicted in FIGS. 5 through 16, it will be understood that the microelectronic device structure 100 also includes the EOA region 106 and periphery region 108, but some features (e.g., some materials, some structures, some openings, some devices) formed as a result of the processing stages described below with reference to FIGS. 5 through 16 may be limited to (e.g., confined within) the array region 104.

Referring to FIG. 6, which is a simplified, partial cross-sectional view of the array region 104 of the microelectronic device structure 100 at an additional processing stage of the method of forming a microelectronic device following the processing stage of FIGS. 4 and 5, portions of the sacrificial material 128 (FIG. 5) within the array region 104 may be removed to form sacrificial line structures 132. The sacrificial line structures 132 may horizontally extend in parallel with one another in the Y-direction, and may be separated from one another in the X-direction by first openings 130 (e.g., first trenches). As described in further detail below, the formation of the sacrificial line structures 132 and the first openings 130 may facilitate the subsequent formation of self-aligned contact structures (e.g., self-aligned digit line contact structures, self-aligned cell contact structures) for the microelectronic device structure 100. In addition, the formation of the sacrificial line structures 132 and the first openings 130 may facilitate the subsequent formation of digit lines for the microelectronic device structure 100 by way of a damascene process, as also described in further detail below.

A vertical height in the Z-direction of each of the sacrificial line structures 132 may be within a range from about 20 nm to about 100 nm, such as from about 30 nm to about 60 nm, or from about 35 nm to about 45 nm. In some embodiments, each of the sacrificial line structures 132 has a vertical height within a range of from about 35 nm to about 45 nm.

Horizontal widths and positions in the X-direction of the sacrificial line structures 132 may at least partially depend on horizontal widths and positions in the X-direction of the projecting portions 113 of the base structure 102, the conductive line structures 112, and the insulative structures 116. Each of the sacrificial line structures 132 may have a horizontal width and a horizontal position permitting a horizontal center of the sacrificial line structures 132 in the X-direction to be substantially horizontally aligned with a horizontal center in the X-direction of one of the projecting portions 113 of the base structure 102, and also permitting a horizontal center in the X-direction of each of the first openings 130 horizontally neighboring the sacrificial line structures 132 be substantially aligned with a horizontal center in the X-direction of an additional one of the projecting portions 113 of the base structure 102. In some embodiments, each of the sacrificial line structures 132 is formed to horizontally overlap, in the X-direction, one of the projecting portions 113 of the base structure 102 and two (2) of the insulative structures 116 (and, hence, two (2) of the conductive line structures 112) horizontally neighboring the projecting portion 113 of the base structure 102. A ratio of the horizontal width of an individual sacrificial line structure 132 to the horizontal width of an individual first opening 130 may be within range of from about 1.5:1 to about 3.0:1, such as from about 1.75:1 to about 2.5:1, or about 2.0:1. Each of the sacrificial line structures 132 may, for example, be formed to have a horizontal width in the X-direction within a range of from about 10 nm to about 60 nm, such as from about 15 nm to about 50 nm, or from about 20 nm to about 40 nm. In some embodiments, each of the sacrificial line structures 132 is formed to have a horizontal width in the X-direction within a range of from about 15 nm to about 30 nm. A pitch between two sacrificial line structures 132 horizontally neighboring may be within a range of from about 10 nm to about 100 nm, such as from about 15 nm to about 75 nm, from about 15 nm to about 50 nm, from 20 nm to about 50 nm, or from about 25 nm to about 35 nm.

The first openings 130 may be formed to horizontally alternate with the sacrificial line structures 132 in the X-direction. Each first openings 130 may horizontal extend in the X-direction between two (2) of the insulative structures 116 (and, hence, between two (2) of the conductive line structures 112) horizontally neighboring one another in the X-direction. In some embodiments, an individual first opening 130 is formed to horizontally overlap each of the two (2) of the insulative structures 116 (and, hence, each of the two (2) of the conductive line structures 112) most horizontally proximate thereto. In additional embodiments, an individual first opening 130 is not formed to horizontally overlap each of the two (2) of the insulative structures 116 (and, hence, each of the two (2) of the conductive line structures 112) most horizontally proximate thereto. For example, the horizontal distance in the X-direction between the two (2) of the insulative structures 116 may be greater than the maximum horizontal width in the X-direction of the individual first opening 130. Each of the first openings 130 may, for example, be formed to have a horizontal width in the X-direction within a range from about 8 nm to about 20 nm, such as from about 8 nm to about 15 nm, or from about 9 nm to about 12 nm. An aspect ratio (AR) of each of the first openings 130 may be within a range from about 10:1 to about 2:1, such as from about 6:1 to about 2:1, or from about from 5:1 to about 3:1.

Referring to next to FIG. 7A, which is a simplified, partial top-down view of the array region 104 of the microelectronic device structure 100 at an additional processing stage of the method of forming a microelectronic device following the processing stage of FIG. 6, fill structures 134, plug structures 138 (e.g., cell contact structures), and isolation structures 140 may be formed within the first openings 130 (FIG. 6). Some of the isolation structures 140 may horizontally alternate with the plug structures 138 in the Y-direction, and other of the isolation structures 140 may horizontally alternate with the fill structures 134 in the Y-direction. In addition, the plug structures 138 may alternate with the sacrificial line structures 132 in the X-direction, and may collectively be interposed between pairs of the fill structures 134 in the X-direction. FIG. 7B is a simplified, partial cross-sectional view of the array region 104 of the microelectronic device structure 100 at the processing stage of FIG. 7A about the line A-A shown in FIG. 7A. FIG. 7C is a simplified, partial cross-sectional view of the array region 104 of the microelectronic device structure 100 at the processing stage of FIG. 7A about the line B-B shown in FIG. 7A.

Referring to FIG. 7B, the fill structures 134 may be formed to vertically terminate on or within the ILD material 110, and the plug structures 138 may be formed to vertically extend through the ILD material 110 and contact the projecting portions 113 of the base structure 102. A lower boundary 136 of an individual plug structure 138 may vertically underlie a lower boundary of the ILD material 110. The lower boundaries 136 of the plug structures 138 may be positioned vertically between upper boundaries and lower vertical boundaries of the insulative structures 116. In some embodiments, the lower boundaries 136 of the plug structures 138 are positioned vertically above lower boundaries of the insulative structures 116. Put another way, the lower boundaries 136 of the plug structures 138 may be positioned vertically above upper boundaries (e.g., upper surfaces) of the conductive line structures 112. In addition embodiments, the lower boundaries 136 of the plug structures 138 are positioned vertically below the lower boundaries of the insulative structures 116. As shown in FIG. 7B, upper boundaries (e.g., upper surfaces) of the fill structures 134 and the plug structures 138 may be substantially coplanar with upper boundaries (e.g., upper surfaces) of the sacrificial line structures 132.

The fill structures 134 may positioned at or proximate horizontal boundaries of the array region 104 of the microelectronic device structure 100. The plug structures 138 may collectively be positioned horizontally between pairs of the fill structures 134, and may be dispersed throughout the horizontal area of the array region 104. The horizontal positions in the X-direction of the fill structures 134 and the plug structures 138 may correspond to the horizontal positions in the X-direction of the first openings 130 (FIG. 6) in which the fill structures 134 and the plug structures 138 are formed. As shown in FIG. 7B, some pairs of the insulative structures 116 (and, hence, some pairs of the conductive line structures 112) may include one of the plug structures 138 horizontally interposed therebetween in the X-direction, and some other pairs of the insulative structures 116 (and, hence, some other pairs of the conductive line structures 112) may not include one of the plug structures 138 horizontally interposed therebetween in the X-direction.

The fill structures 134 and the plug structures 138 may individually be formed of and include one or more of semiconductor material and conductive material. In some embodiments, the fill structures 134 and the plug structures 138 are individually formed of and include semiconductor material, such as polycrystalline silicon. In additional embodiments, the fill structures 134 and the plug structures 138 are individually formed of and include conductive material, such one or more of at least one metal, at least one an alloy, at least one conductive metal-containing material, and at least one conductively doped semiconductor material. In further embodiments, the fill structures 134 and the plug structures 138 are individually formed of and include a combination of semiconductor material (e.g., polysilicon) and conductive material (e.g., metal). For example, relatively lower portions of the fill structures 134 and the plug structures 138 may be formed of and include semiconductor material (e.g., polysilicon), and relatively higher portions of the fill structures 134 and the plug structures 138 may be formed of and include conductive material (e.g., metal). In some embodiments, upper portions of the fill structures 134 and the plug structures 138 having vertical dimensions within a range of from about 5 nm to about 25 nm (e.g., from about 10 nm to about 15 nm) have a different material composition than relatively lower portions of the fill structures 134 and the plug structures 138.

Referring to FIG. 7C, the isolation structures 140 may be formed to vertically terminate on or within the ILD material 110. A lower boundaries of the isolation structures 140 may vertically overlie the lower boundaries 136 (FIG. 7B) of plug structures 138 (FIG. 7B). As shown in FIG. 7B, upper boundaries (e.g., upper surfaces) of the isolation structures 140 may be substantially coplanar with upper boundaries (e.g., upper surfaces) of the sacrificial line structures 132.

The isolation structures 140 may be dispersed throughout the horizontal area of the array region 104 of the microelectronic device structure 100. The horizontal positions in the X-direction of the fill structures 134 and the plug structures 138 may correspond to the horizontal positions in the X-direction of the first openings 130 (FIG. 6) in which the isolation structures 140 are formed. As shown in FIGS. 7A and 7C, the isolation structures 140 may be horizontally interposed in the X-direction between horizontally neighboring pairs of sacrificial line structures 132; and may be horizontally interposed in the Y-direction between horizontally neighboring pairs of the plug structures 138 (FIG. 7A) and/or horizontally neighboring pairs of the fill structures 134 (FIG. 7A). For example, an individual isolation structure 140 may horizontally extend from and between two (2) of the sacrificial line structures 132 in the X-direction, and may horizontally extend from and between two (2) of the plug structures 138 in the Y-direction orthogonal to the X-direction.

The isolation structures 140 may individually be formed of and include insulative material. A material composition of the isolation structures 140 may be different than a material composition of the sacrificial line structure 132. The sacrificial line structure 132 may be selectively etchable relative to the isolation structures 140 during mutual exposure to a first etchant, and the isolation structures 140 may be selectively etchable relative to sacrificial line structure 132 during mutual exposure to a second etchant different than the first etchant. In some embodiments, the isolation structures 140 are individually formed of and include carbon-doped dielectric nitride material. In additional embodiments, the isolation structures 140 are individually formed of and include carbon-doped dielectric oxide material. In further embodiments, the isolation structures 140 are individually formed of and include low-K dielectric material (e.g., one or more of SiOₓC_{y}, SiOₓN_{y}, SiCₓO_{y}H_{z}, and SiOₓC_{y}N_{z}).

In some embodiments, the fill structures 134 and the plug structures 138 are formed prior to the formation of the isolation structures 140. Portions of the ILD material 110 may be removed (e.g., by way of so-called “punch through” etching) at predetermined horizontal positions of the plug structures 138, and then the resulting openings in the ILD material 110 as well as the first openings 130 (FIG. 6) may be filled (e.g., substantially filled) with fill material (e.g., polycrystalline silicon) to form fill material line structures horizontal alternating with the sacrificial line structures 132 in the X-direction. Thereafter, portions of the fill material line structures at locations corresponding to predetermined positions of the isolation structures 140 may be removed (e.g., using conventional patterning processes, such as conventional photolithographic patterning process), while maintaining the sacrificial line structures 132 and additional portions of the fill material line structures, to form the fill structures 134 and the plug structures 138. Second openings may horizontally intervene, in the Y-direction, between horizontally neighboring fill structures 134 and between horizontally neighboring plug structures 138. Thereafter the isolation structures 140 may be formed (e.g., using conventional material deposition processes, such as a non-conformal material deposition process; and conventional material removal processes, such as a conventional CMP process) within the second openings.

In additional embodiments, the isolation structures 140 are formed prior to the fill structures 134 and the plug structures 138. The first openings 130 (FIG. 6) may be filled (e.g., substantially filled) with insulative material to form insulative line structures horizontal alternating with the sacrificial line structures 132 in the X-direction. Thereafter, portions of the insulative line structures at locations corresponding to predetermined positions of the fill structures 134 and the plug structures 138 may be removed (e.g., using conventional patterning processes, such as conventional photolithographic patterning process), while maintaining additional portions of the insulative line structures, to form the isolation structures 140. Second openings may horizontally intervene, in the Y-direction, between horizontally neighboring isolation structures 140. Next, portions of the ILD material 110 exposed by some of the second openings at predetermined horizontal positions for the plug structures 138 may be removed (e.g., by way of so-called “punch through” etching), and then the resulting openings in the ILD material 110 as well as the second openings and may be filled (e.g., substantially filled) with fill material (e.g., polysilicon). Portions of the fill material overlying upper boundaries of the isolation structures 140 and the sacrificial line structures 132 may then be removed (e.g., by way of a conventional CMP process) to form the fill structures 134 and the plug structures 138.

Referring to next to FIG. 8, which is a simplified, partial cross-sectional view of the array region 104 of the microelectronic device structure 100 at an additional processing stage of the method of forming a microelectronic device following the processing stage of FIGS. 7A through 7C, the sacrificial line structures 132 (FIGS. 7A through 7C) may be selectively removed relative to the fill structures 134, the plug structures 138, the isolation structures 140 (FIGS. 7A and 7C), and the ILD material 110 to form linear trenches 142 in place of the sacrificial line structures 132 (FIGS. 7A through 7C). Thereafter, dielectric fill material 146, and, optionally, sacrificial spacer material 148 may be formed within the linear trenches 142. The dielectric fill material 146 and the sacrificial spacer material 148 (if any) may substantially fill the linear trenches 142 resulting from the selective removal of the sacrificial line structures 132 (FIGS. 7A through 7C).

The sacrificial line structures 132 (FIGS. 7A through 7C) may be selectively removed relative to the fill structures 134, the plug structures 138, the isolation structures 140 (FIGS. 7A and 7C), and the ILD material 110 by exposing the microelectronic device structure 100 to at least one etchant formulated to remove the sacrificial line structures 132 (FIGS. 7A through 7C) at a faster rate than fill structures 134, the plug structures 138, the isolation structures 140 (FIGS. 7A and 7C), and the ILD material 110. By way of non-limiting example, if the sacrificial line structures 132 (FIGS. 7A through 7C) are formed of and include dielectric nitride material (e.g., Si₃N₄), the microelectronic device structure 100 may be exposed to an etching process (e.g., a vapor etching process) employing phosphoric acid (H₃O₄P) as an etchant.

The dielectric fill material 146 may be formed of and include insulative material, such as one or more of dielectric oxide material (e.g., SiOₓ, such as SiO₂; phosphosilicate glass; borosilicate glass; borophosphosilicate glass; fluorosilicate glass; aluminum oxide; high-k oxide, such as HfOₓ; a combination thereof), dielectric nitride material (e.g., SiN_{y}, dielectric oxynitride material (e.g., SiOₓN_{y}), dielectric carbonitride material (e.g., SiCₓN_{y}), and dielectric carboxynitride material (e.g., SiOₓC_{y}N_{z}), and amorphous carbon. In some embodiments, the dielectric fill material 146 is formed of and includes dielectric oxide materials (e.g., SiOₓ, such as SiO₂). The dielectric fill material 146 may be formed within the linear trenches resulting from the removal of the sacrificial line structures 132 (FIGS. 7A through 7C) through conventional deposition process, such as a conventional non-conformal deposition process (e.g., a conventional PVD process). In some the dielectric fill material 146 is formed through a spin on dielectric (SOD) process. After filling the linear trenches resulting from the removal of the sacrificial line structures 132 (FIGS. 7A through 7C) with the dielectric fill material 146, portions of the dielectric fill material 146 outside of the boundaries of the linear trenches may be removed (e.g., by way of CMP processing). Upper boundaries of the dielectric fill material 146 may be formed to be substantially coplanar with upper boundaries of the fill structures 134, the plug structures 138, and the isolation structures 140 (FIGS. 7A and 7C).

Optionally, the sacrificial spacer material 148 may be formed (e.g., conformally formed) within the linear trenches resulting from the removal of the sacrificial line structures 132 (FIGS. 7A through 7C) prior to forming of the dielectric fill material 146. The sacrificial spacer material 148, if any, may be horizontally interposed between the dielectric fill material 146 and the fill structures 134, the plug structures 138, the isolation structures 140 (FIGS. 7A and 7C), and the ILD material 110. In some embodiments, the sacrificial spacer material 148 is formed to a limit a subsequent removal process to the removal of the dielectric fill material 146, as described in further detail below.

If formed, the sacrificial spacer material 148 may be formed of and include at least one material having etch selectively relative to the dielectric fill material 146 and the ILD material 110. In some embodiments, the sacrificial spacer material 148 is formed of and includes a dielectric oxide material, such as AlOₓ (e.g., Al₂O₃). In additional embodiments, the sacrificial spacer material 148 is formed of and includes a different dielectric material (e.g., a nitride dielectric material, an oxynitride dielectric material, a carbonitride dielectric material, a carboxynitride dielectric material) may be employed in place of the oxide dielectric material forming the sacrificial spacer material 148, so long as the different dielectric material has etch selectivity relative to the dielectric fill material 146 and the ILD material 110.

The sacrificial spacer material 148, if any, may be formed to any desired thickness, such as a thickness less than or equal to about 10 nm, less than or equal to about 6 nm, or less than or equal to about 4 nm. The thickness of the sacrificial spacer material 148 may at least partially depend on the geometric configuration (e.g., dimensions, shapes) of the linear trenches within which the sacrificial spacer material 148 is formed.

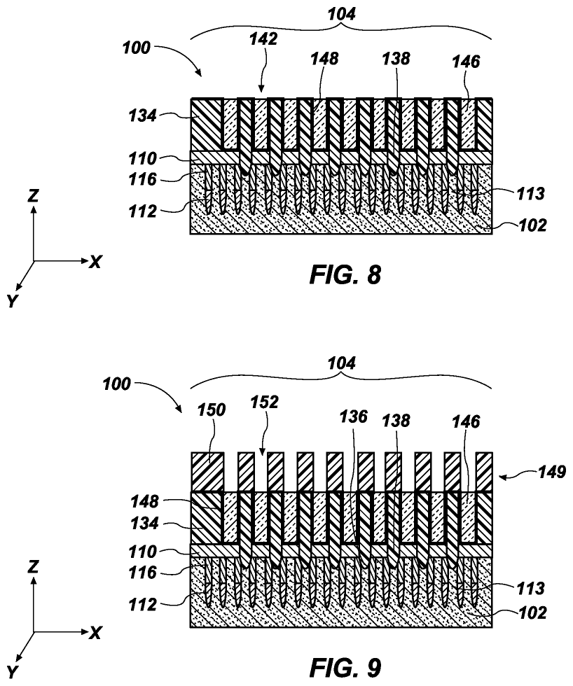

Referring next to FIG. 9, which is a simplified, partial cross-sectional view of the array region 104 of the microelectronic device structure 100 at an additional processing stage of the method of forming a microelectronic device following the processing stage of FIG. 8, a patterned mask 149 may be formed over the fill structures 134, the plug structures 138, the isolation structures 140 (FIGS. 7A and 7C), the dielectric fill material 146, and the sacrificial spacer material 148 (if any). As shown in FIG. 9, the patterned mask 149 may be formed to include masking material 150, and pattern openings 152 interposed between horizontally neighboring masking material 150.

As shown in FIG. 9, the masking material 150 of the patterned mask 149 may be formed to cover and horizontally extend across (e.g., in the X-direction and the Y-direction) the fill structures 134 and the plug structures 138, as well as portions of the dielectric fill material 146 and the sacrificial spacer material 148 (if any) within the linear trenches 142 (FIG. 8). The masking material 150 may at least partially (e.g., substantially) horizontally overlap the fill structures 134 and the plug structures 138. In some embodiments, the masking material 150 substantially horizontally aligned in the X-direction with one of the fill structures 134 or one of the plug structures 138, and substantially horizontally across an upper surface of the with one of the fill structures 134 or one of the plug structures 138. Portions of the sacrificial spacer material 148 (if any) may be vertically interposed between the masking material 150 and the fill structures 134, the plug structures 138, and portions of the dielectric fill material 146.

The masking material 150 of the patterned mask 149 may be formed of an include at least one material facilitating subsequent removal of exposed portions of the dielectric fill material 146 relative to non-exposed (e.g., covered) portions of the dielectric fill material 146, the sacrificial spacer material 148 (if any), the fill structures 134, and the plug structures 138. In some embodiments, the masking material 150 is formed of and includes a photoresist material (e.g., a positive tone photoresist material, a negative tone photoresist material). In additional embodiments, the masking material 150 is formed of and includes a different material, such as a hard mask material (e.g., one or more of amorphous carbon and doped amorphous carbon).

Still referring to FIG. 9, the pattern openings 152 within the patterned mask 149 may be formed to horizontally extend across and expose portions of the dielectric fill material 146 within the linear trenches 142 (FIG. 8). The pattern openings 152 may at least partially (e.g., substantially) horizontally overlap the dielectric fill material 146. In some embodiments, each of the pattern openings 152 is substantially horizontally aligned in the X-direction with a line of the dielectric fill material 146 within one of the pattern openings 152; and is substantially horizontally aligned in the Y-direction with a horizontal center of at least one of the plug structures 138. At least some of the pattern openings 152 may individually be formed to horizontally extend in the X-direction from and between a pair of the plug structures 138. The pattern openings 152 may be configured (e.g., sized, shaped) and positioned to expose portions (e.g., less than entireties) of upper surfaces of the dielectric fill material 146 within the linear trenches 142 (FIG. 8). The pattern openings 152 may also expose portions (e.g., less than entireties) of the sacrificial spacer material 148 (if any) within horizontal boundaries of the linear trenches 142 (FIG. 8).

In some embodiments, a dimension of an individual pattern opening 152 in the X-direction is less than or equal to about a distance between plug structures 138 horizontally neighboring one another in the X-direction. By way of non-limiting example, the dimension of an individual pattern opening 152 in the X-direction may be within a range from about 15 nm to about 35 nm, such as from about 15 nm to about 30 nm, or from about 15 nm to about 25 nm. In addition, in some embodiments, a dimension of an individual pattern opening 152 in the Y-direction is less than or equal to a dimension in the Y-direction of an individual plug structure 138 adjacent thereto in the X-direction. By way of non-limiting example, the dimension of an individual pattern opening 152 in the Y-direction may be within a range from about 15 nm to about 35 nm, such as from about 15 nm to about 30 nm, or from about 15 nm to about 25 nm. In some embodiments, a dimension of an individual plug structure 138 in the X-direction is substantially equal to a dimension of the individual plug structure 138 in the Y-direction.

Referring to next to FIG. 10A, which is a simplified, partial cross-sectional view of the array region 104 of the microelectronic device structure 100 at an additional processing stage of the method of forming a microelectronic device following the processing stage of FIG. 9, the dielectric fill material 146 (FIG. 9) exposed by the pattern openings 152 (FIG. 9) in the patterned mask 149 (FIG. 9) may be removed to form first trenches 153, and then portions of the sacrificial spacer material 148 (if any), the ILD material 110, and the projecting portions 113 of the base structure 102 underlying the portions of the dielectric fill material 146 within horizontal areas of the first trenches 153 may be removed to form first contact openings 154. The first contact openings 154 may be viewed as vertical extensions of the first trenches 153 at desirable locations within the array region 104, as described in further detail below. The first contact openings 154 may expose portions of the insulative structures 116 and remaining portions of the projecting portions 113 of the base structure 102. FIG. 10B is a simplified, partial top-down view of the array region 104 of the microelectronic device structure 100 at the processing stage of FIG. 10A, wherein the cross-sectional view of FIG. 10A is taken about line C-C shown in FIG. 10B. The first trenches 153 may horizontally extend in the parallel in the Y-direction. The first trenches 153 may occupy volumes previously occupied by the dielectric fill material 146 (FIG. 9). The sacrificial spacer material 148 (if any) may define boundaries (e.g., horizontal boundaries, vertical boundaries) of the first trenches 153. The sacrificial spacer material 148 may facilitate self-alignment of the first trenches 153 during formation, by way of a difference in etch rate of the dielectric fill material 146 (FIG. 9) relative to an etch rate of the sacrificial spacer material 148 (if any) during mutual exposure to a given etchant. The dielectric fill material 146 (FIG. 9) may be selectively etchable relative to the sacrificial spacer material 148 (if any). Accordingly, centerlines in the X-direction of the pattern openings 152 (FIG. 9) in the patterned mask 149 (FIG. 9) do not need to be substantially aligned centerlines in the X-direction of portions of the dielectric fill material 146 (FIG. 9) horizontally interposed in the X-direction between the plug structures 138 to facilitate the formation of the first trenches 153. Rather, the pattern openings 152 (FIG. 9) in the patterned mask 149 (FIG. 9) may simply horizontally overlap the dielectric fill material 146 (FIG. 9) to facilitate the formation of the first trenches 153.

In some embodiments, a material removal process to form the first trenches 153 comprises at least one etching process, such as one or more of a wet etching process and a vapor etching process. By way of non-limiting example, depending at least on the material compositions of the dielectric fill material 146 (FIG. 9) and the sacrificial spacer material 148 (if any), an etchant employed to form the first trenches 153 may comprise one or more of hydrofluoric acid (HF), a buffered oxide etchant (BOE), nitric acid (HNO₃), and tetramethylammonium hydroxide (TMAH). In some embodiments, the etching process includes treating the microelectronic device structure 100 with a solution including water and HF at a ratio within a range of from about 500:1 to about 100:1. The dielectric fill material 146 (FIG. 9) may be exposed to the etchant using conventional processes (e.g., a spin-coating process, a spray-coating process, an immersion-coating process, a vapor-coating process, a soaking process, combinations thereof) and conventional processing equipment, which are not described in detail herein.

With continued reference to FIG. 10A, the first contact openings 154 may be formed to vertically extend below upper vertical boundaries of the insulative structures 116. Lower vertical boundaries of the contact openings 154 may be positioned between lower vertical boundaries and upper vertical boundaries of the insulative structures 116. The lower vertical boundaries of the first contact openings 154 may vertically overlie lower vertical boundaries of the plug structures 138. In some embodiments a vertical depth in the Z-direction of the first contact openings 154 is within a range of from about 10 nm to about 50 nm, such as from about nm to about 45 nm, from about 20 nm to about 40, or from about 20 nm to about 30 nm.

Referring collectively to FIGS. 10A and 10B, the first contact openings 154 may be formed to horizontally overlap the plug structures 138 in the Y-direction. As shown in FIG. 10B, in some embodiments, horizontal centerlines of the first contact openings 154 in the Y-direction are horizontally aligned in the Y-direction with horizontal centerlines in the Y-direction of the plug structures 138 most horizontally proximate thereto in the X-direction. In addition, first contact openings 154 most horizontally proximate to one another in the X-direction may be horizontally offset from one another in the Y-direction. As shown in FIG. 10A, an upper portion of an individual first contact opening 154 may horizontally extend in the X-direction from and between two of the plug structures 138 horizontally neighboring one another in the X-direction; and lower portion of the first contact opening 154 may horizontally extend in the X-direction from and between two of the insulative structures 116 horizontally neighboring one another in the X-direction. The first contact openings 154 may individually be formed to have desired horizontal dimensions (e.g., in the X-direction, in the Y-direction), such as a horizontal dimension in the X-direction within a range of from about 7 nm to about 25 nm (e.g., from about 10 nm to about 25 nm, from about 15 nm to about 25 nm, from about 15 nm to about nm), and horizontal dimension in the Y-direction within a range of from about 7 nm to about nm (e.g., from about 10 nm to about 25 nm, from about 15 nm to about 25 nm, from about 15 nm to about 20 nm). In some embodiments, a horizontal dimension of an individual first contact opening 154 in the X-direction is equal to a horizontal dimension of the first contact opening 154 in the Y-direction.

In some embodiments, an additional material removal process to form the first contact openings 154 comprises at least one etching process, such as one or more of a vapor etching process and a dry etching process. The additional material removal process to form the first contact openings 154 may, for example, comprise a so-called “punch through” etch. The etching process may result in the removal of portions of the sacrificial spacer material 148 (if any), the ILD material 110, and upper regions of the projecting portions 113 of the base structure 102 without substantial removal of the STI structures 114 and the insulative structures 116. In some embodiments, additional material removal process to remove portions of the sacrificial spacer material 148 (if any), the ILD material 110, and upper regions of the projecting portions 113 of the base structure 102 and form the contact openings 154 comprises a single anisotropic dry etch process (e.g., using one or more of chlorine gas, boron trichloride (BCl₃), oxygen, and argon), where the etch chemistries are in situ changed for “punching through” the sacrificial spacer material 148, for “punching through” the ILD material 110, and for removing the upper regions of the projecting portions 113 of the base structure 102. In additional embodiments, the additional material removal process to remove portions of the sacrificial spacer material 148 (if any), the ILD material 110, and the upper regions of the projecting portions 113 of the base structure 102 comprises multiple (e.g., two or more), separate and distinct etch processes. In some embodiments, the additional material removal process to form the contact openings 154 is preceded by a deposition of another material (e.g., mask material) to protect the fill structures 134 and plug structures 138 during the additional material removal process.

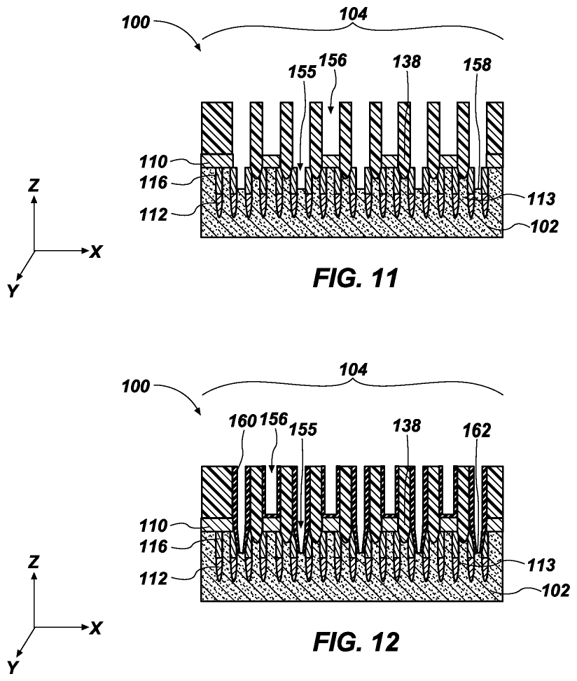

Referring to FIG. 11, which is a simplified, partial cross-sectional view of the array region 104 of the microelectronic device structure 100 shown in FIG. 10A at an additional processing stage of the method of forming a microelectronic device following the processing stage of FIGS. 10A and 10B, the second optional mask material 144 (FIG. 10A) (if any) may be removed to form second trenches 156 from the first trenches 153 (FIG. 10A), and the first contact openings 154 (FIG. 10A) may be vertically extended into the projecting portions 113 of the base structure 102 to form second contact openings 155 from the first contact openings 154 (FIG. 10A). The second contact openings 155 may be considered vertical extensions of the second trenches 156. The vertical extension of the first contact openings 154 (FIG. 10A) may remove upper sections of the projecting portions 113 of the base structure 102. Lower vertical boundaries 158 of the second contact openings 155 may be positioned vertically above upper boundaries (e.g., upper surfaces) of the conductive line structures 112.

The second optional mask material 144 (FIG. 10A) (if any) and the upper sections of the projecting portions 113 of the base structure 102 may be selectively removed (e.g., relative to the fill structures 134, the plug structures 138, the ILD material 110, the insulative structure 116 materials, and the conductive line structure 112) using at least one etchant, such as one or more of hydrofluoric acid (HF), a phosphoric acid, acetic acid, nitric acid, hydrochloric acid, aqua regia, or hydrogen peroxide. In some embodiments, the etchant comprises a solution including water and HF at a ratio within a range of from about 50:1 to about 10:1. The microelectronic device structure 100 may be exposed to the etchant using conventional processes (e.g., a spin-coating process, a spray-coating process, an immersion-coating process, a vapor-coating process, a soaking process, combinations thereof) and conventional processing equipment, which are not described in detail herein. In other embodiments, the etchant includes an undiluted form of HF.

Referring to FIG. 12, which is a simplified, partial cross-sectional view of the array region 104 of the microelectronic device structure 100 shown in FIG. 11 at an additional processing stage of the method of forming a microelectronic device following the processing stage of FIG. 11, at least one digit line spacer material 160 may be formed (e.g., conformally formed) within the second contact openings 155 and second trenches 156. The digit line spacer material 160 may partially (e.g., less than completely) fill the second contact openings 155 and the second trenches 156. The digit line spacer material 160 may serve as a digit line contact isolation material, as described in further detail below. The digit line spacer material 160 may be formed to have a thickness within a range of from about 1 nm to about 5 nm, such as from about 2 nm to about 4 nm, or from about 2 nm to about 3 nm.

The digit line spacer material 160 may be formed of and include dielectric material. In some embodiments, the digit line spacer material 160 is formed of and includes a dielectric nitride material (e.g., SiN_{y}, such as Si₃N₄). In additional embodiments, the digit line spacer material 160 is formed of and includes at least one low-K dielectric material, such as one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{z}N_{y}). By way of non-limiting example, the digit line spacer material 160 may be formed of and include SiCₓO_{y}H_{z}. In some such embodiments, hydrogen migration within and from the SiCₓO_{y}H_{z} may result in the formation of air pockets (e.g., air bubbles) within the digit line conformal spacer material 160.

As shown in FIG. 12, upper surfaces of the projecting portions 113 of the base structure 102 defining lower vertical boundaries of the second contact openings 155 may be at least partially free of the digit line spacer material 160 thereon. Put another way, portions of the upper surfaces of the projecting portions 113 of the base structure 102 may be not be covered by the digit line spacer material 160 following the formation of the digit line spacer material 160 within the second contact openings 155 and the second trenches 156.

The digit line spacer material 160 may be formed through a multistep process. In some embodiments, such as embodiments wherein the digit line spacer material 160 is formed of and includes dielectric nitride material, the digit line spacer material 160 is formed (e.g., conformally formed) inside and outside of the second contact openings 155 and the second trenches 156, portions of the digit line spacer material 160 overlying upper boundaries of the second trenches 156 are removed (e.g., by way of CMP), and then additional portions of the digit line spacer material 160 at the bottoms of the second contact openings 155 are removed by way a “punch through” etch to expose the upper surfaces of the projecting portions 113 of the base structure 102. In additional embodiments, a “punch through” etch is not employed to remove portions of the digit line spacer material 160 on the upper surfaces of the projecting portions 113 of the base structure 102, as described in further detail below. For example, the digit line spacer material 160 may be formed through one or more of an epitaxial growth process and a material deposition process that precludes the digit line spacer material 160 from being formed on portions of the upper surfaces of the projecting portions 113 of the base structure 102. Furthermore, in some embodiments, portions (e.g., upper portions) of the digit line spacer material 160 are subsequently removed and replaced with additional digit line spacer material (e.g., low-K dielectric material in place of dielectric nitride material), as also described in further detail below.

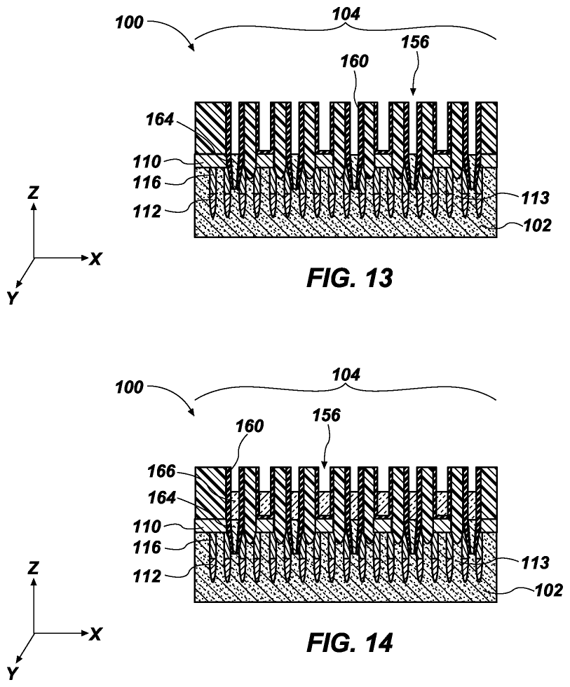

Referring to next to FIG. 13, which is a simplified, partial cross-sectional view of the array region 104 of the microelectronic device structure 100 shown in FIG. 12 at an additional processing stage of the method of forming a microelectronic device following the processing stage of FIG. 12, conductive contacts 164 (e.g., digit line contacts) are formed within portions of the second contact openings 155 (FIG. 12) remaining unoccupied by the digit line spacer material 160. The digit line spacer material 160 may electrically isolate the plug structures 138 from the conductive contacts 164.

The conductive contacts 164 may individually be formed of and include conductive material. In some embodiments, the conductive contacts 164 individually include multiple conductive materials. As a non-limiting example, the conductive contacts 164 may individually include conductive material and conductive barrier material on or over the conductive material. The conductive material may include one or more of at least one elemental metal (e.g., W, Ti, Mo, Nb, V, Hf, Ta, Cr, Zr, Fe, Ru, Os, Co, Rh, Ir, Ni, Pa, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), at least one conductively doped semiconductor material (e.g., conductively doped polysilicon, conductively doped Ge, conductively-doped SiGe), and at least one conductive metal-containing material (e.g., a conductive metal nitride, a conductive metal silicide, a conductive metal carbide, a conductive metal oxide). The conductive barrier material may, for example, include one or more of elemental metal, conductive silicide material (e.g., cobalt silicide (CoSiₓ), tungsten silicide (WSiₓ), tantalum silicide (TaSiₓ), molybdenum silicide (MoSiₓ), nickel silicide (NiSiₓ), and titanium silicide (TiSiₓ)), and conductive nitride material (e.g., tungsten nitride (WN_{y}), tantalum nitride (TaN_{y}), titanium nitride (TiN_{y}), and molybdenum nitride (MoNₓ)).

The conductive contacts 164 are individually formed to be positioned horizontally between two (2) of insulative structures 116 (and, hence, two (2) of the conductive line structures 112). Each conductive contact 164 may have an upper boundary (e.g., upper surface) vertically above upper boundaries (e.g., upper surfaces) of the insulative structures 116, and a lower boundary (e.g., a lower surface) vertically above lower boundaries (e.g., lower surfaces) of the insulative structures 116. In some embodiments, upper boundaries of the conductive contacts 164 are formed to be substantially vertically aligned with an upper boundary (e.g., upper surface) of the ILD material 110. In additional embodiments, upper boundaries of the conductive contacts 164 are formed to be vertically offset from (e.g., vertically overlie, vertically underlie) the upper boundary (e.g., upper surface) of the ILD material 110. For example, upper boundaries of the conductive contacts 164 may be formed to be substantially vertically aligned with upper boundaries (e.g., upper surfaces) of portions of the digit line spacer material 160 vertically overlying and in physical contact with the ILD material 110. The lower boundaries of the conductive contacts 164 may be formed to vertically overlie upper boundaries (e.g., upper surfaces) of the conductive line structures 112.

In some embodiments, to form the conductive contacts 164, portions of the digit line spacer material 160 are subjected to a “punch through” etch to expose the projecting portions 113 of the base structure 102, and then a seed material is formed (e.g., epitaxially grown) at the resulting termination points 162 to facilitate the formation of the conductive contacts 164. The conductive contacts 164 may be formed using the seed material, and may individual include the seed material. In some embodiments, portions of the conductive contacts 164 at least partially epitaxially grown using the seed material. In additional embodiments, portions of the conductive contacts 164 are deposited on the seed material. A material removal process may optionally be employed following formation (e.g., epitaxial growth, deposition) of material of the conductive contacts 164 to facilitate desired upper vertical boundaries of the conductive contacts 164. In addition, optionally, following the formation of the conductive contacts 164, portions of the digit line spacer material 160 vertically overlying the upper vertical boundaries of the conductive contacts 164 may be removed (e.g., wet etched), replaced with a different digit line spacer material, and then the different digit line spacer material may be subject to an additional “punch through” etch to expose the conductive contacts 164. By way of non-limiting example, if the digit line spacer material 160 is formed of and includes a dielectric nitride material, following the formation of conductive contacts 164 portions of the digit line spacer material 160 overlying the upper vertical boundaries of the digit line spacer material 160 may be removed (e.g., wet etched), a second digit line spacer material formed of and including a low-K dielectric material may be formed (e.g., conformally formed) to partially fill remaining portions of the second trenches 156, and then the second digit line spacer material may be subjected to an additional “punch through” etch to expose the conductive contacts 164.

In additional embodiments, the conductive contacts 164 are formed without the use of a “punch through” etch through the digit line spacer material 160. For example, an epitaxial growth process employed to form digit line spacer material 160 may also be employed to form the seed material for the conductive contacts 164. A first processing act of the epitaxial growth process may include epitaxially growing a silicon-containing material for the digit line spacer material 160. The first processing act may then be halted and a second processing act may be effectuated to grow the seed material at the lower vertical boundaries of the second contact openings 155 (FIG. 12). Upon achieving the desired dimensions for the seed material of the conductive contacts 164, the second processing act may be halted and a third processing act may be effectuated to continue epitaxially growth of the silicon-containing material and form the digit line spacer material 160. Thereafter, a fourth processing act may be effectuated to form (e.g., epitaxially grow, deposit) additional portions of the conductive contacts 164 using the seed material.

In further embodiments, a sacrificial material (e.g., spin-on-carbon (SOC)) is formed to fill the second contact openings 155 (FIG. 12) prior to the formation of the digit line spacer material 160, and the digit line spacer material 160 is formed to within the second trenches 156 and may cover the sacrificial material. Thereafter, the digit line spacer material 160 is subjected to a “punch through” etch to expose the sacrificial material, the sacrificial material is removed (e.g., exhumed) from the second contact openings 155 (FIG. 12) to expose the projecting portions 113 of the base structure 102, and then a seed material is deposited at the resulting termination points 162 to facilitate the formation of the conductive contacts 164. The conductive contacts 164 may, for example, be epitaxially grown using the seed material. A material removal process may optionally be employed following the epitaxial growth process to facilitate desired upper vertical boundaries of the conductive contacts 164. In addition, optionally, following the formation of the conductive contacts 164, portions of the digit line spacer material 160 vertically overlying the upper vertical boundaries of the conductive contacts 164 may be removed (e.g., wet etched), replaced with a different digit line spacer material, and then the different digit line spacer material may be subject to an additional “punch through” etch to expose the conductive contacts 164.

Referring to next to FIG. 14, which is a simplified, partial cross-sectional view of the array region 104 of the microelectronic device structure 100 shown in FIG. 13 at an additional processing stage of the method of forming a microelectronic device following the processing stage of FIG. 13, digit line structures 166 (e.g., additional conductive line structures) may be formed within and may partially fill (e.g., less than completely) the second trenches 156. The digit line structures 166 may contact (e.g., physically contact, electrically contact) the conductive contacts 164, and may be formed to horizontally extend in parallel with one another in the Y-direction. Upper boundaries of the digit line structures 166 may vertically underlie upper boundaries of the plug structures 138.

The digit line structures 166 may be formed of and include conductive material. For example, the digit line structures 166 may be formed to include one or more of metal (e.g., tungsten, titanium, nickel, platinum, gold, copper), metal alloy, metal-containing material (e.g., metal nitrides, metal silicides, metal carbides, metal oxides), and conductively-doped semiconductor material (e.g., conductively doped silicon). By way of non-limiting example, the digit line structures 166 may individually comprise one or more of titanium nitride (TiN_{y}), tantalum nitride (TaN_{y}), tungsten nitride (WN_{y}), titanium aluminum nitride (TiAlₓN_{y}), elemental titanium (Ti), elemental platinum (Pt), elemental rhodium (Rh), elemental iridium (Ir), iridium oxide (IrOₓ), elemental ruthenium (Ru), ruthenium oxide (RuOₓ), and alloys thereof. In some embodiments, the digit line structures 166 are formed of and include a conductive material having relatively lower electrical resistivity than the conductive contacts 164.

The digit line structures 166 may formed by depositing conductive material within the second trenches 156, and then vertically recessing the conductive material to form the digit line structures 166. In some embodiments, the deposition process comprises one or more of a CVD process and an ALD process employing at least one metal-containing precursor (e.g., tungsten-containing precursor) and at least one reducing agent (e.g., hydrogen (H₂) gas). In some such embodiments, the metal-containing precursor is substantially free of fluorine atoms, such as a tungsten chloride (WClₓ, where x is an integer between 2 and 6). The use of WClₓ may mitigate the risk of damage to the conductive contacts 164 as compared, for example, to fluorine-based precursors. In additional embodiments, the deposition process comprises a PVD process.

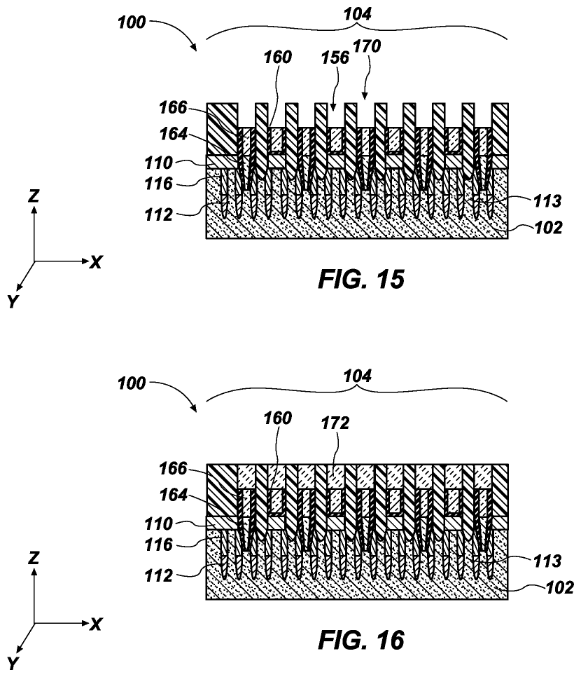

Referring to next to FIG. 15, which is a simplified, partial cross-sectional view of the array region 104 of the microelectronic device structure 100 shown in FIG. 14 at an additional processing stage of the method of forming a microelectronic device following the processing stage of FIG. 15, portions of the digit line spacer material 160 vertically overlying the upper vertical boundaries of the digit line structures 166 may be removed to form third trenches 170. The removal process may expose upper portions of side surfaces of the plug structures 138 vertically overlying the upper vertical boundaries of the digit line structures 166. Lower vertical boundaries of the third trenches 170 may be at least partially defined by upper surfaces of the digit line structures 166 and upper surfaces of remaining portions of the digit line spacer material 160. Horizontal boundaries of the third trenches 170 may be at least partially defined by the upper portions of the side surfaces of the plug structures 138.

Referring to next to FIG. 16, which is a simplified, partial cross-sectional view of the array region 104 of the microelectronic device structure 100 shown in FIG. 15 at an additional processing stage of the method of forming a microelectronic device following the processing stage of FIG. 16, capping dielectric structures 172 may be formed on or over the digit line structures 166. The capping dielectric structures 172 may substantially fill the third trenches 170 (FIG. 15). As shown in FIG. 16, an upper vertical boundaries (e.g., upper surfaces) of the capping dielectric structures 172 may be formed to be substantially co-planar with upper vertical boundaries (e.g., upper surfaces) of the plug structures 138.

The capping dielectric structures 172 may be formed of and include dielectric material, such as one or more of a dielectric oxide material, dielectric nitride material, dielectric oxynitride material, and dielectric carboxynitride material. In some embodiments, the capping dielectric structures 172 are formed of and include dielectric nitride material, such as silicon nitride (Si₃N₄). The capping dielectric structures 172 may individually be substantially homogeneous, or may individually be heterogeneous.

Following the formation of the capping dielectric structures 172, the microelectronic device structure 100 may be subjected to additional processing to form a microelectronic device (e.g., a memory device). By way of non-limiting example, storage node devices (e.g., capacitors, memory elements) may be formed vertically over and in electrical communication with the plug structures 138. In some embodiments, conductive redistribution layer (RDL) structures are also formed vertically between and in electrical communication with the plug structures 138 and the storage node devices. The conductive RDL structures may, for example, be employed to facilitate a horizontal pattern (e.g., a horizontal arrangement) of the storage node devices that is different than a horizontal pattern of the plug structures 138, while electrically connecting the plug structures 138 to the storage node devices.

Thus, in accordance with embodiments of the disclosure, a method of forming a microelectronic device comprises forming interlayer dielectric material over a base structure comprising semiconductive structures separated from one another by conductive line structures. Sacrificial line structures separated from one another by trenches are formed over the interlayer dielectric material. The sacrificial line structures horizontally overlap some of the semiconductive structures, and the trenches horizontally overlap some other of the semiconductive structures. Plug structures are formed within horizontal areas of the trenches and extend through the interlayer dielectric material and into the some other of the semiconductive structures. The sacrificial line structures are replaced with additional trenches. Conductive contact structures are formed within horizontal areas of the additional trenches and extend through the interlayer dielectric material and into the some of the semiconductive structures. Additional conductive line structures are formed within the additional trenches and in contact with the conductive contact structures.

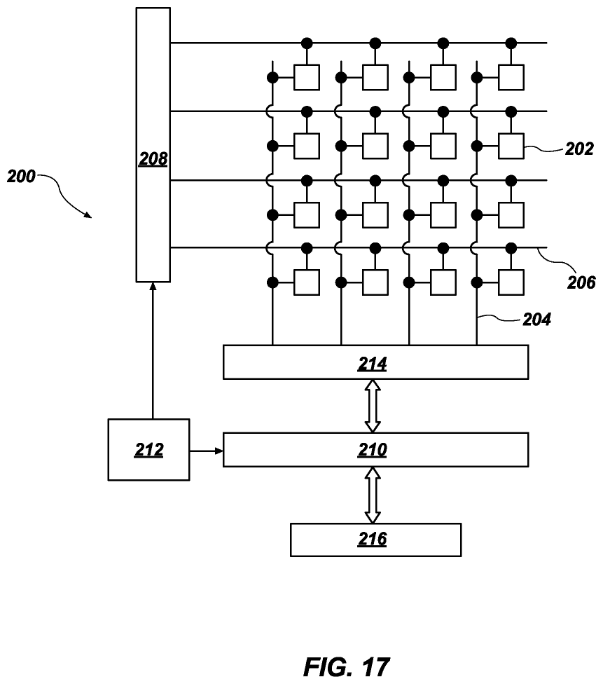

Microelectronic device structures (e.g., the microelectronic device structure 100 at or following the processing stage previously described with reference to FIG. 16) of the disclosure may be included in microelectronic devices of the disclosure. As a non-limiting example, FIG. 17 illustrates a functional block diagram of a memory device 200, in accordance with an embodiment of the disclosure. The memory device 200 may include, for example, an embodiment of the microelectronic device structure 100 at or following the processing stage previously described with reference to FIG. 16. As shown in FIG. 17, the memory device 200 may include memory cells 202, digit lines 204, word lines 206, a row decoder 208, a column decoder 210, a memory controller 212, a sense device 214, and an input/output device 216.

The memory cells 202 of the memory device 200 are programmable to at least two different logic states (e.g., logic 0 and logic 1). Each memory cell 202 may individually include a capacitor and transistor (e.g., a pass transistor). The capacitor stores a charge representative of the programmable logic state (e.g., a charged capacitor may represent a first logic state, such as a logic 1; and an uncharged capacitor may represent a second logic state, such as a logic 0) of the memory cell 202. The transistor grants access to the capacitor upon application (e.g., by way of one of the word lines 206) of a minimum threshold voltage to a semiconductive channel thereof for operations (e.g., reading, writing, rewriting) on the capacitor.

The digit lines 204 are connected to the capacitors of the memory cells 202 by way of the transistors of the memory cells 202. The transistors of the memory cells 202 may include, for example, an embodiment of the microelectronic device structure 100 previously described herein with reference to FIGS. 5A and 5B. The word lines 206 extend perpendicular to the digit lines 204, and are connected to gates of the transistors of the memory cells 202. Operations may be performed on the memory cells 202 by activating appropriate digit lines 204 and word lines 206. Activating a digit line 204 or a word line 206 may include applying a voltage potential to the digit line 204 or the word line 206. Each column of memory cells 202 may individually be connected to one of the digit lines 204, and each row of the memory cells 202 may individually be connected to one of the word lines 206. Individual memory cells 202 may be addressed and accessed through the intersections (e.g., cross points) of the digit lines 204 and the word lines 206.

The memory controller 212 may control the operations of memory cells 202 through various components, including the row decoder 208, the column decoder 210, and the sense device 214 (e.g., local I/O device). The memory controller 212 may generate row address signals that are directed to the row decoder 208 to activate (e.g., apply a voltage potential to) predetermined word lines 206, and may generate column address signals that are directed to the column decoder 210 to activate (e.g., apply a voltage potential to) predetermined digit lines 204. The sense device 214 may include sense amplifiers configured and operated to receive digit line inputs from the digit lines selected by the column decoder 210 and to generate digital data values during read operations. The memory controller 212 may also generate and control various voltage potentials employed during the operation of the memory device 200. In general, the amplitude, shape, and/or duration of an applied voltage may be adjusted (e.g., varied), and may be different for various operations of the memory device 200.

During use and operation of the memory device 200, after being accessed, a memory cell 202 may be read (e.g., sensed) by the sense device 214. The sense device 214 may compare a signal (e.g., a voltage) of an appropriate digit line 204 to a reference signal in order to determine the logic state of the memory cell 202. If, for example, the digit line 204 has a higher voltage than the reference voltage, the sense device 214 may determine that the stored logic state of the memory cell 202 is a logic 1, and vice versa. The sense device 214 may include transistors and amplifiers to detect and amplify a difference in the signals (commonly referred to in the art as “latching”). The detected logic state of a memory cell 202 may be output through the column decoder 210 to the input/output device 216. In addition, a memory cell 202 may be set (e.g., written) by similarly activating an appropriate word line 206 and an appropriate digit line 204 of the memory device 200. By controlling the digit line 204 while the word line 206 is activated, the memory cell 202 may be set (e.g., a logic value may be stored in the memory cell 202). The column decoder 210 may accept data from the input/output device 216 to be written to the memory cells 202. Furthermore, a memory cell 202 may also be refreshed (e.g., recharged) by reading the memory cell 202. The read operation will place the contents of the memory cell 202 on the appropriate digit line 204, which is then pulled up to full level (e.g., full charge or discharge) by the sense device 214. When the word line 206 associated with the memory cell 202 is deactivated, all of memory cells 202 in the row associated with the word line 206 are restored to full charge or discharge.

Thus, a microelectronic device according to embodiments of the disclosure comprises interlayer dielectric material over a base structure comprising semiconductive structures alternating with conductive line structures in a first horizontal direction; conductive contact structures vertically extending through the interlayer dielectric material and in physical contact with some of the semiconductive structures; additional conductive line structures in physical contact with the conductive contact structures and horizontally extending in parallel in a second horizontal direction orthogonal to the first horizontal direction; plug structures comprising semiconductive material horizontal alternating with the additional conductive line structures in the first horizontal direction, the plug structures vertically extending through the interlayer dielectric material and in physical contact with some other of the semiconductive structures; and dielectric liner structures horizontally interposed between the plug structures and the conductive contact structures and the additional conductive line structures, portions of the dielectric liner structures at vertical elevations of the conductive contact structures having different material compositions than additional portions of the dielectric liner structures at vertical elevations of the additional conductive line structures.

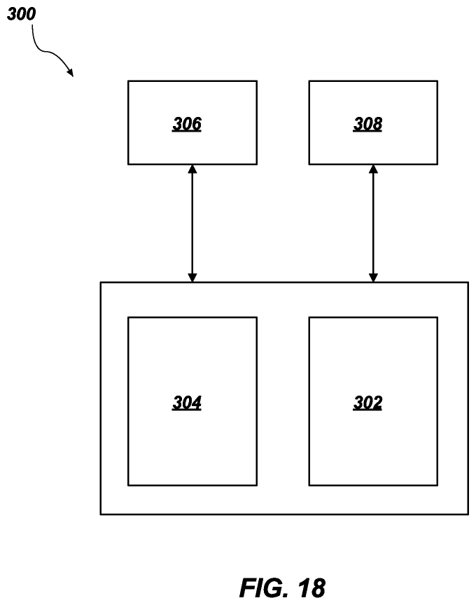

Microelectronic devices (e.g., the memory device 200 shown in FIG. 17) including microelectronic device structures (e.g., the microelectronic device structure 100 shown in FIG. 16) in accordance with embodiments of the disclosure may be used in embodiments of electronic systems of the disclosure. For example, FIG. 18 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, an embodiment of a microelectronic device (e.g., the memory device 200 shown in FIG. 17) previously described herein. The electronic system 300 may further include at least one electronic signal processor device 304 (often referred to as a “microprocessor”). The electronic signal processor device 304 may, optionally, include an embodiment a microelectronic device (e.g., the memory device 200 shown in FIG. 17) previously described herein. While the memory device 302 and the electronic signal processor device 304 are depicted as two (2) separate devices in FIG. 18, in additional embodiments, a single (e.g., only one) memory/processor device having the functionalities of the memory device 302 and the electronic signal processor device 304 is included in the electronic system 300. In such embodiments, the memory/processor device may include an embodiment of a microelectronic device structure (e.g., the microelectronic device structure 100 shown in FIG. 16) previously described herein, and/or an embodiment of a microelectronic device (e.g., the memory device 200 shown in FIG. 17) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

Thus, an electronic system according to embodiments of the disclosure comprises an input device, an output device, a processor device operably coupled to the input device and the output device, and a memory device operably coupled to the processor device and comprising a microelectronic device structure. The microelectronic device structure comprises interlayer dielectric material over a base structure comprising semiconductive structures horizontally alternating with word line structures; digit line contact structures extending through the interlayer dielectric material and to some of the semiconductive structures; digit line structures on the digit line contact structures; cell contact structures horizontal alternating with the digit line structures, the cell contact structures extending through the interlayer dielectric material and to some other of the semiconductive; dielectric liner structures horizontally extending from the cell contact structures to the digit line contact structures and the digit line structures, the dielectric liner structures comprising: lower portions at vertical positions of the digit line contact structures and comprising dielectric nitride material; and upper portions at vertical positions of the digit line structures and comprising low-K dielectric material; and storage node devices in electrical communicate with the cell contact structures.

The structures, devices, methods, and systems of the disclosure advantageously facilitate one or more of improved microelectronic device performance, reduced costs (e.g., manufacturing costs, material costs), increased miniaturization of components, and greater packaging density as compared to conventional structures, conventional devices, conventional methods, and conventional systems. For example, the methods of the disclosure may facilitate the formation of self-aligned features (e.g., the plug structures 138, the conductive contacts 164) using damascene processes, thereby decreasing probability of misalignment the features, decreasing process complexity, and/or decreasing the risk of undesirable damage to neighboring features relative to conventional processes. The structure, devices, methods, and systems of the disclosure may improve scalability, efficiency, and simplicity as compared to conventional structures, conventional devices, conventional methods, and conventional systems.

While the disclosure is susceptible to various modifications and alternative forms, specific embodiments have been shown by way of example in the drawings and have been described in detail herein. However, the disclosure is not intended to be limited to the particular forms disclosed. Rather, the disclosure is to cover all modifications, equivalents, and alternatives falling within the scope of the disclosure as defined by the following appended claims and their legal equivalents.

What is claimed is:

1. A method of forming a microelectronic device, comprising:
forming interlayer dielectric material over a base structure comprising semiconductive structures separated from one another by conductive line structures;
forming sacrificial line structures separated from one another by trenches over the interlayer dielectric material, the sacrificial line structures horizontally overlapping some of the semiconductive structures, and the trenches horizontally overlapping some other of the semiconductive structures;
forming plug structures within horizontal areas of the trenches and extending through the interlayer dielectric material and into the some other of the semiconductive structures;
replacing the sacrificial line structures with additional trenches;
forming conductive contact structures within horizontal areas of the additional trenches and extending through the interlayer dielectric material and into the some of the semiconductive structures; and
forming additional conductive line structures within the additional trenches and in contact with the conductive contact structures.

2. The method of claim 1, wherein forming sacrificial line structures comprises:
forming a dielectric nitride material over of the interlayer dielectric material; and
removing portions of the dielectric nitride material at horizontal positions of the some other of the semiconductive structures to form the trenches, the sacrificial line structures comprising remaining portions of the dielectric nitride material.

3. The method of claim 1, wherein forming plug structures comprises:
forming a dielectric fill material within the trenches;
removing portions of the dielectric fill material, the interlayer dielectric material, and the some other of the semiconductive structures to from openings; and
filling the openings with one or more of semiconductive material and conductive material to form the plug structures.

4. The method of claim 3, wherein replacing the sacrificial line structures with additional trenches comprises:
selectively removing the sacrificial line structures to form preliminary additional trenches;
forming dielectric liner material on exposed surfaces of the plug structures, the dielectric fill material, and the interlayer dielectric material defining the preliminary additional trenches;
forming an additional dielectric fill material to substantially fill portions of the preliminary additional trenches unoccupied by the dielectric liner material;
forming a patterned mask structure over the dielectric fill material and additional dielectric fill material; and
selectively removing the additional dielectric fill material through openings in the patterned mask structure to form the additional trenches.

5. The method of claim 4, further comprising selecting the dielectric liner material to comprise aluminum oxide.

6. The method of claim 4, wherein forming conductive contact structures comprises:
removing portions of the interlayer dielectric material and into the some of the semiconductive structures to form contact openings projecting from the additional trenches;
forming additional dielectric liner material within the additional trenches and the contact openings; and
forming the conductive contact structures within portions of the contact openings unoccupied by the additional dielectric liner material, the conductive contact structures in physical contact with the some of the semiconductive structures.

7. The method of claim 6, wherein forming the conductive contact structures within portions of the contact openings unoccupied by the additional dielectric liner material comprises:
removing portions of the additional dielectric liner material at bottoms of the contact openings to expose the some of the semiconductive structures; and
at least partially epitaxially growing the conductive contact structures within the contact openings after removing the portions of the additional dielectric liner material at the bottoms of the contact openings.

8. The method of claim 6, wherein forming the conductive contact structures within portions of the contact openings unoccupied by the additional dielectric liner material comprises forming the conductive contact structures to be in physical contact with the some of the semiconductive structures without etching the additional dielectric liner material.

9. The method of claim 6, further comprising replacing portions of the additional dielectric liner material vertically overlying the conductive contact structures with a further dielectric liner material prior to forming the conductive line structures, the further dielectric liner material having a different material composition than the additional dielectric liner material.

10. The method of claim 9, further comprising:
selecting the additional dielectric liner material to comprise a dielectric nitride material; and
selecting the further dielectric liner material to comprise a low-K dielectric material.

11. The method of claim 10, further comprising removing portions of the low-K dielectric material vertically overlying upper boundaries of the additional conductive line structures.

12. The method of claim 1, further comprising filling portions of the additional trenches vertically overlying the additional conductive line structures with dielectric capping material.

13. A microelectronic device, comprising:
interlayer dielectric material over a base structure comprising semiconductive structures alternating with conductive line structures in a first horizontal direction;
conductive contact structures vertically extending through the interlayer dielectric material and in physical contact with some of the semiconductive structures;
additional conductive line structures in physical contact with the conductive contact structures and horizontally extending in parallel in a second horizontal direction orthogonal to the first horizontal direction;
plug structures comprising semiconductive material horizontal alternating with the additional conductive line structures in the first horizontal direction, the plug structures vertically extending through the interlayer dielectric material and in physical contact with some other of the semiconductive structures; and
dielectric liner structures horizontally interposed between the plug structures and the conductive contact structures and the additional conductive line structures, portions of the dielectric liner structures at vertical elevations of the conductive contact structures having different material compositions than additional portions of the dielectric liner structures at vertical elevations of the additional conductive line structures.

14. The microelectronic device of claim 13, further comprising insulative structures vertically interposed between the conductive line structures and the interlayer dielectric material, the insulative structures vertically overlapping the conductive contact structures and having lower boundaries below lower vertical boundaries of the conductive contact structures.

15. The microelectronic device of claim 13, wherein the conductive contact structures individually comprise metal silicide material and metal nitride material.

16. The microelectronic device of claim 13, wherein the conductive contact structures comprise epitaxial material.

17. The microelectronic device of claim 13, wherein:
the portions of the dielectric liner structures at the vertical elevations of the conductive contact structures comprise dielectric nitride material; and
the additional portions of the dielectric liner structures at the vertical elevations of the additional conductive line structures comprise low-K dielectric material.

18. The microelectronic device of claim 13, further comprising dielectric capping material in physical contact with upper surfaces of the additional conductive line structures, upper surfaces of the dielectric liner structures, and side surfaces of the plug structures.

19. An electronic system, comprising:
an input device;
an output device;
a processor device operably coupled to the input device and the output device; and
a memory device operably coupled to the processor device and comprising a microelectronic device structure, the microelectronic device structure comprising:
interlayer dielectric material over a base structure comprising semiconductive structures horizontally alternating with word line structures;
digit line contact structures extending through the interlayer dielectric material and to some of the semiconductive structures;
digit line structures on the digit line contact structures;
cell contact structures horizontal alternating with the digit line structures, the cell contact structures extending through the interlayer dielectric material and to some other of the semiconductive structures;
dielectric liner structures horizontally extending from the cell contact structures to the digit line contact structures and the digit line structures, the dielectric liner structures comprising:
lower portions at vertical positions of the digit line contact structures and comprising dielectric nitride material; and
upper portions at vertical positions of the digit line structures and comprising low-K dielectric material; and
storage node devices in electrical communicate with the cell contact structures.

20. The electronic system of claim 19, wherein the memory device comprises a dynamic random access memory (DRAM) device.
